(19) United States
(12) Patent Application Publication
(10) Pub. No.: US 2026/0107780 A1
(43) Pub. Date: Apr. 16, 2026

(54) TAPER ROUTING IN HIGH-SPEED INTERFACES FOR COMPENSATING IMPEDANCE MISMATCHES

(71) Applicant: Infineon Technologies Americas Corp., El Segundo, CA (US)

(72) Inventors: Shaowu HUANG, Los Altos, CA (US); Dance Wu, Palo Alto, CA (US)

(73) Assignee: Infineon Technologies Americas Corp., El Segundo, CA (US)

(21) Appl. No.: 19/350,601

(22) Filed: Oct. 6, 2025

Related U.S. Application Data
(60) Provisional application No. 63/707,848, filed on Oct. 16, 2024.

(51) Int. Cl. H01L 23/66; H01P 1/00

(52) U.S. Cl. CPC H10W 44/20; H01P 1/00

(57) ABSTRACT

A system and method of mitigating impedance mismatches in high-speed electronic systems. The method includes forming a conductive region having a geometry that varies along a longitudinal direction to create a taper. The method includes configuring the taper to produce a spatially varying characteristic impedance along the conductive region. The method includes coupling a first electronic component to a first edge located at one end of the conductive region. The method includes coupling a second electronic component to a second edge located at an opposite end of the conductive region. The method includes transitioning the characteristic impedance from a first impedance at the first edge to a second impedance at the second edge to reduce an impedance mismatch between the first electronic component and the second electronic component.

### CROSS-REFERENCE TO RELATED APPLICATIONS

This application claims the benefit of U.S. Provisional Application Serial No. 63/707,848 entitled “Taper Routing in High-Speed Interfaces for Compensating Impedance Mismatches,” filed Oct. 16, 2024, the disclosure of which is incorporated herein by reference in its entirety.

### TECHNICAL FIELD

The present disclosure relates generally to the field of high-speed electronic interconnects, and more particularly, to systems and methods for mitigating impedance mismatches in high-speed electronic systems using taper routing techniques implemented within printed circuit boards (PCBs) and semiconductor packages.

### BACKGROUND

In high-speed electronic systems, signal transmission quality is heavily influenced by the impedance characteristics of the transmission path. Each segment of the signal path, whether in a printed circuit board, package substrate, connector, or cable, has a characteristic impedance that ideally should match the impedance of the transmitter and receiver. When there is a mismatch between these impedances, part of the signal energy is reflected back toward the source, resulting in signal degradation, increased return loss, and potential data errors. These reflections can distort the signal waveform, reduce timing margins, and include overall system reliability. To ensure maximum power transfer and maintain signal integrity, it is desirable to achieve a continuous impedance profile throughout the signal path, minimizing discontinuities that lead to reflections.

### BRIEF DESCRIPTION OF THE DRAWINGS

The present disclosure is illustrated by way of example, and not by way of limitation, in the figures of the accompanying drawings in which like reference numerals refer to similar elements and in which:

FIG. 1A illustrates an example high-speed electronic system including a high-impedance differential transmitter and a low-impedance differential receiver that communicate via an outer-edge-tapered PCB trace to resolve the impedance mismatch, in accordance with some embodiments;

FIG. 1B illustrates an example high-speed electronic system including a high-impedance differential transmitter and a low-impedance differential receiver that communicate via an inner-edge-tapered PCB trace to resolve the impedance mismatch, in accordance with some embodiments;

FIG. 1C illustrates an example high-speed electronic system including a high-impedance differential transmitter and a low-impedance differential receiver that communicate via a dual-edge-tapered PCB trace to resolve the impedance mismatch, in accordance with some embodiments;

FIG. 2A illustrates an example high-speed electronic system including a low-impedance differential transmitter and a high-impedance differential receiver that communicate via an outer-edge-tapered PCB trace to resolve the impedance mismatch, in accordance with some embodiments;

FIG. 2B illustrates an example high-speed electronic system including a low-impedance differential transmitter and a high-impedance differential receiver that communicate via an inner-edge-tapered PCB trace to resolve the impedance mismatch, in accordance with some embodiments;

FIG. 2C illustrates an example high-speed electronic system including a low-impedance differential transmitter and a high-impedance differential receiver that communicate via a dual-edge-tapered PCB trace to resolve the impedance mismatch, in accordance with some embodiments;

FIG. 3 illustrates an example high-speed electronic system including a high-impedance single-ended transmitter and a low-impedance single-ended receiver that communicate via a dual-edge-tapered PCB trace to resolve the impedance mismatch, in accordance with some embodiments;

FIG. 4 illustrates an example high-speed electronic system including a high-impedance differential transmitter and a low-impedance differential receiver that communicate via a piece-wise tapered PCB trace to resolve the impedance mismatch, in accordance with some embodiments;

FIG. 5 illustrates an example high-speed electronic system including a high-impedance differential transmitter and a low-impedance differential receiver that communicate via a tapered PCB trace with decreasing trace spacing to resolve the impedance mismatch, in accordance with some embodiments;

FIG. 6 illustrates an example high-speed electronic system including a high-impedance differential transmitter and a low-impedance differential receiver that communicate via a tapered PCB trace with increasing trace spacing to resolve the impedance mismatch, in accordance with some embodiments;

FIG. 7 illustrates an example high-speed electronic system including a low-impedance differential transmitter and a high-impedance differential receiver that communicate across a cable or discrete device using multiple tapered PCB traces to resolve multiple impedance mismatches, in accordance with some embodiments;

FIG. 8 illustrates an example high-speed electronic system including a high-impedance differential transmitter and a low-impedance differential receiver that communicate across a cable or discrete device using multiple tapered PCB traces to resolve multiple impedance mismatches, in accordance with some embodiments;

FIG. 9 illustrates an example high-speed electronic system including a single-ended or differential transmitter and a single-ended or differential receiver that communicate across multiple circuit stages using multiple single-ended or differential PCB traces, in accordance with some embodiments; and

FIG. 10 illustrates an example semiconductor package configured to resolve impedance matching between wirebonds and PCB, in accordance with some embodiments;

FIG. 11 illustrates an example semiconductor package configured to resolve impedance matching between wirebonds and PCB, in accordance with some embodiments;

FIG. 12 is a flow diagram of a method of mitigating impedance mismatches in high-speed electronic systems using taper routing techniques implemented within PCBs and semiconductor packages; and

FIG. 13 is a block diagram of an example computing device that may perform one or more of the operations described herein, in accordance with some embodiments.

### DETAILED DESCRIPTION

The following description sets forth numerous specific details such as examples of specific systems, components, methods, and so forth, in order to provide a good understanding of various embodiments of the techniques described herein for mitigating impedance mismatches in high-speed electronic systems using taper routing techniques implemented within printed circuit boards (PCBs) and semiconductor packages. It will be apparent to one skilled in the art, however, that at least some embodiments may be practiced without these specific details. In other instances, well-known components, elements, or methods are not described in detail or are presented in a simple block diagram format to avoid unnecessarily obscuring the techniques described herein. Thus, the specific details set forth hereinafter are merely exemplary. Particular implementations may vary from these exemplary details and still be contemplated to be within the scope of the present disclosure.

In high-speed signal interfaces, impedance mismatches between the transmitter (TX) and receiver (RX) can significantly degrade signal integrity. This issue is particularly prevalent in automotive systems, where a serializer-deserializer (SerDes) interface may connect a networking system-on-chip (SoC), such as an automotive switch SoC, to a computing SoC, such as an automotive graphics processing unit (GPU) SoC. These SoCs are often sourced from different vendors, and their SerDes input/output (I/O) ports may exhibit differing differential impedances. For example, a SerDes port on the switch SoC may have a characteristic impedance of 100 ohms, while the corresponding port on the GPU SoC may have an impedance of 85 ohms. Such mismatches can result in increased return loss, degraded signal performance, and potential link failures.

In some automotive platform designs, 10 gigabit per second serializer-deserializer (SerDes) links may connect GPU SoCs that conform to the Small Form Factor (SFF) Committee INF-8077i specification, titled “10 Gigabit Small Form Factor Pluggable (XFP) Module Specification”, which specifies an 85-ohm differential impedance. These links may interface with switch SoCs that conform to the IEEE 802.3-2018 KR specification, formally known as “10GBASE-KR: IEEE 802.3 Physical Layer Specification for 10 Gb/s over Backplane”, which specifies a 100-ohm differential impedance. This impedance mismatch between the SerDes ports of the GPU SoC and the switch SoC reduces the operational margin of the SerDes link, adversely affecting the eye diagram and overall signal integrity.

Impedance mismatches are not limited to chip-to-chip interfaces. They also occur along PCB traces due to the presence of components such as alternating current (AC) coupling capacitors, which are used to block direct current (DC) while allowing high-speed AC signals to pass between devices. Other contributors to impedance discontinuities include common mode chokes (CMCs) and cable connectors. Additionally, mismatches may arise within semiconductor packages due to wirebond structures and ball grid array (BGA) pin field routing, which inherently introduce higher impedance. These discontinuities contribute to return loss and further degrade performance in high-speed SerDes and Ethernet channels.

Accordingly, there is a long-felt need for improved techniques that compensate for or mitigate impedance mismatches in high-speed signal interfaces.

Aspects of the present disclosure provide routing techniques that replace conventional uniform trace routing with taper routing that mitigate impedance mismatches in high-speed electronic systems, including those implemented within PCBs and semiconductor packages. For example, taper routing may be used to address impedance mismatches in automotive Ethernet systems, where differences in differential impedance between components can degrade signal quality.

The taper routing techniques described herein are applicable at both the printed circuit board level. For example, they may be used to match impedances across components such as alternating current coupling capacitors, common mode chokes, common mode termination structures, and connectors. These techniques are also applicable at the semiconductor package level, where impedance mismatches may result from wirebond structures or ball grid array pin field routing.

Taper routing may be implemented using a variety of taper geometries, including linear, piecewise, polynomial, exponential, and Klopfenstein profiles. These techniques are suitable for both differential signal interfaces and single-ended signal interfaces, providing a flexible and scalable solution for improving signal quality in high-speed electronic systems.

Example applications include memory systems, automotive Ethernet systems (used for in-vehicle networking), Fibre Channel networks (used in storage area networks), Synchronous Optical Networking or SONET-based communication systems (used in telecommunications infrastructure), Peripheral Component Interconnect Express or PCI Express interfaces (used for high-speed data transfer in computing systems), and high performance computing platforms, among others.

This approach significantly improves signal integrity, particularly return loss, in high-speed interfaces such as SerDes and Ethernet. It achieves these enhancements without introducing additional cost or increasing power consumption. Furthermore, it does not negatively affect insertion loss and has only negligible impact on other electrical performance metrics, including mode conversion.

In an illustrative embodiment, a signal routing system includes a conductive region having a geometry that varies along a longitudinal direction to form a taper, the taper being configured to produce a spatially varying characteristic impedance along the conductive region. The characteristic impedance transitions from a first impedance at a first edge located at one end of the conductive region to a second impedance at a second edge located at an opposite end of the conductive region. The spatially varying characteristic impedance is configured to reduce an impedance mismatch between a first electronic component coupled to the first edge and a second electronic component coupled to the second edge.

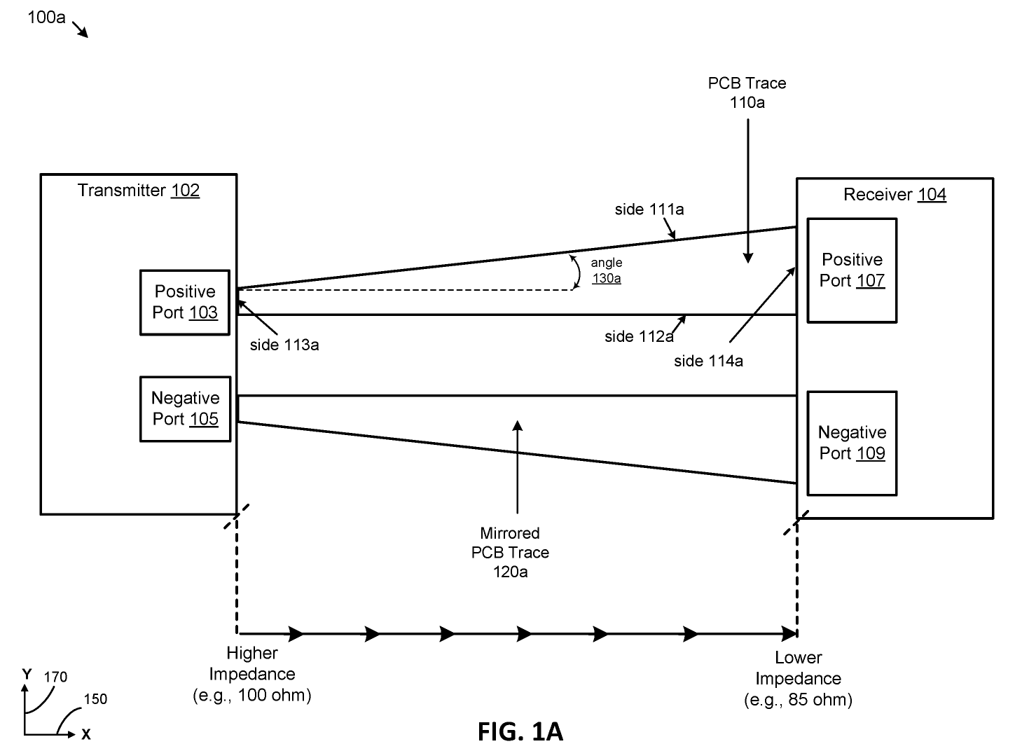

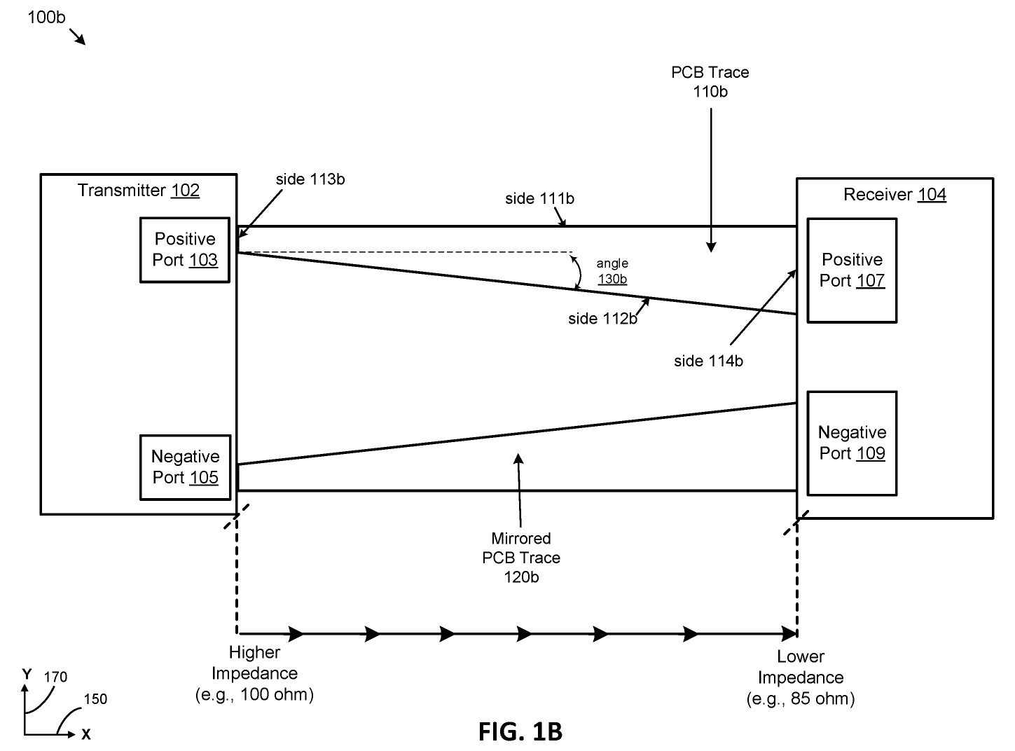

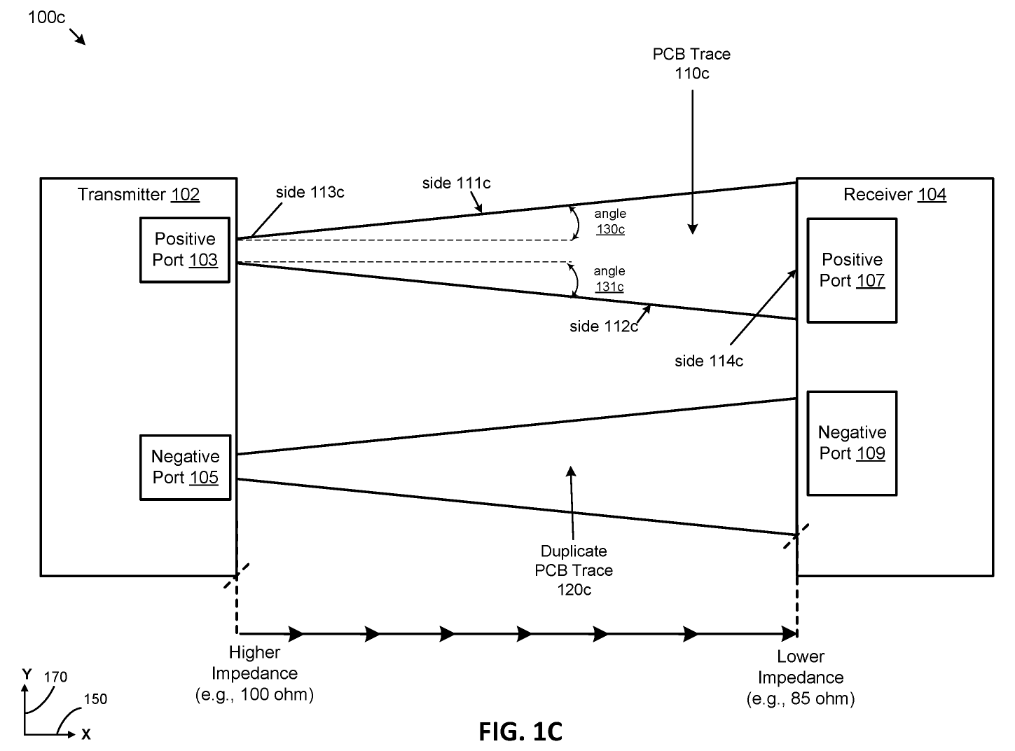

As discussed in further detail below with reference to FIGS. 1A-6, various implementations of PCB traces are configured to compensate for or mitigate impedance mismatches in high-speed signal interfaces. A PCB trace may be disposed on a top layer of a PCB (sometimes referred to herein as the PCB board) or within any internal layer of the PCB. For example, a PCB may include, from top to bottom: a silkscreen layer for component labeling; a solder mask layer for protecting copper traces; a top copper layer for signal routing and component mounting; one or more dielectric layers for electrical insulation and mechanical support; internal copper layers for power and ground distribution (in multilayer configurations); additional internal copper layers for internal signal routing; a bottom copper layer; and corresponding bottom solder mask and silkscreen layers.

FIG. 1A illustrates an example high-speed electronic system including a high-impedance differential transmitter and a low-impedance differential receiver that communicate via an outer-edge-tapered PCB trace to resolve the impedance mismatch, in accordance with some embodiments. The high-speed electronic system 100a includes a transmitter 102, implemented as an integrated circuit (IC) device, and a receiver 104, which is also an IC device. The transmitter 102 includes a differential output interface consisting of a positive port 103 and a negative port 105. The receiver 104 includes a differential input interface consisting of a positive port 107 and a negative port 109. The differential output impedance of the transmitter 102 is greater than the differential input impedance of the receiver 104.

As shown in FIG. 1A, the differential output interface has an impedance of 100 ohms, while the differential input interface has an impedance of 85 ohms. However, other embodiments may exhibit different impedance mismatches. In such embodiments, each of the differential output interface and the differential input interface may have an impedance fixed at a value between 50 ohms and 100 ohms, provided that the output impedance remains greater than the input impedance.

The positive port 103 of the transmitter 102 is electrically coupled to the positive port 107 of the receiver 104 via a PCB trace 110a. The PCB trace 110a defines a closed geometric shape including four sides: side 111a having a first length, side 112a having a second length, side 113a having a third length, and side 114a having a fourth length.

Each of the four sides has a different length. For example, side 113a is shorter than side 114a, which is shorter than side 112a, which is shorter than side 111a. Side 113a and side 114a extend vertically along the y-axis 170 and are parallel (or substantially parallel) to one another. Side 112a extends horizontally along the x-axis 150 between side 113a and side 114a. Side 111a also extends between side 113a and side 114a. The four sides complete the closed shape of the PCB trace 110a.

As discussed herein, impedance mismatches along a signal path can lead to increased signal reflections and degraded signal integrity. To mitigate the impedance mismatch resulting from the differential output interface of transmitter 102 having a higher impedance than the differential input interface of receiver 104, side 111a of PCB trace 110a is configured to be tapered. Specifically, side 111a slopes in the positive direction along the y-axis 170 as it extends from its connection with side 113a to its termination at side 114a. The angle 130a formed between side 111a and an imaginary horizontal line parallel to the x-axis 150 and originating at the positive port 103 may be equal to or fall within the range of approximately 0.01 degrees to 0.2 degrees, based on the absolute value.

The negative port 105 of the transmitter 102 is electrically coupled to the negative port 109 of the receiver 104 via a mirrored PCB trace 120a. The mirrored PCB trace 120a is identical in shape and electrical performance to PCB trace 110a, but is vertically flipped relative to PCB trace 110a.

FIG. 1B illustrates an example high-speed electronic system including a high-impedance differential transmitter and a low-impedance differential receiver that communicate via an inner-edge-tapered PCB trace to resolve the impedance mismatch, in accordance with some embodiments. The high-speed electronic system 100b includes the transmitter 102 and the receiver 104 in FIG. 1A, where the output interface of the transmitter 102 has a differential output impedance that is greater than the differential input impedance of the input interface of the receiver 104.

However, unlike the configuration in FIG. 1A, the output interface of the transmitter 102 is electrically coupled to the input interface of the receiver 104 via a PCB trace 110b. The PCB trace 110b defines a closed geometric shape including four sides: side 111b having a first length, side 112b having a second length, side 113b having a third length, and side 114b having a fourth length.

Each of the four sides has a different length. For example, side 113b is shorter than side 114b, which is shorter than side 111b, which is shorter than side 112b. Side 113b and side 114b extend vertically along the y-axis 170 and are parallel (or substantially parallel) to one another. Side 111b extends horizontally along the x-axis 150 between side 113b and side 114b. Side 112b also extends between side 113b and side 114b, thereby completing the closed shape of the PCB trace 110b.

To mitigate the impedance mismatch resulting from the differential output interface of transmitter 102 having a higher impedance than the differential input interface of receiver 104, side 112b of PCB trace 110b is configured to be tapered. Specifically, side 112b slopes in the negative direction along the y-axis 170 as it extends from its connection with side 113b to its termination at side 114b. The angle 130b formed between side 112b and an imaginary horizontal line parallel to the x-axis 150 and originating at the positive port 103 may be equal to or fall within the range of approximately 0.01 degrees to 0.2 degrees, based on the absolute value.

The negative port 105 of the transmitter 102 is electrically coupled to the negative port 109 of the receiver 104 via a mirrored PCB trace 120b. The mirrored PCB trace 120b is identical in shape and electrical performance to PCB trace 110b, but is vertically flipped relative to PCB trace 110b.

FIG. 1C illustrates an example high-speed electronic system including a high-impedance differential transmitter and a low-impedance differential receiver that communicate via a dual-edge-tapered PCB trace to resolve the impedance mismatch, in accordance with some embodiments. The high-speed electronic system 100c includes the transmitter 102 and the receiver 104 in FIG. 1A, where the output interface of the transmitter 102 has a differential output impedance that is greater than the differential input impedance of the input interface of the receiver 104.

However, unlike the configuration in FIG. 1A, the output interface of the transmitter 102 is electrically coupled to the input interface of the receiver 104 via a PCB trace 110c. The PCB trace 110c defines a closed geometric shape including four sides: side 111c having a first length, side 112c having a second length, side 113c having a third length, and side 114c having a fourth length.

Two of the four sides have a different length, while the other two sides have the same length. For example, side 113c is shorter than side 114c, while side 111c has the same length as side 112c. Side 113c and side 114c extend vertically along the y-axis 170 and are parallel (or substantially parallel) to one another. Side 111c and side 112c extend between side 113c and side 114c. All four sides complete the closed shape of the PCB trace 110c.

To mitigate the impedance mismatch resulting from the differential output interface of transmitter 102 having a higher impedance than the differential input interface of receiver 104, both side 111c and side 112c are configured to be tapered. Specifically, side 112c slopes in the negative direction along the y-axis 170 as it extends from its connection with side 113c to its termination at side 114c. Side 111c slopes in the positive direction along the y-axis 170 as it extends from its connection with side 113c to its termination at side 114c.

The angle 130c formed between side 111c and an imaginary horizontal line parallel to the x-axis 150 and originating at the positive port 103 may be equal to or fall within the range of approximately 0.01 degrees to 0.2 degrees, based on the absolute value. The angle 131c formed between side 112c and an imaginary horizontal line parallel to the x-axis 150 and originating at the positive port 103 may be equal to or fall within the range of approximately 0.01 degrees to 0.2 degrees, based on the absolute value.

The negative port 105 of the transmitter 102 is electrically coupled to the negative port 109 of the receiver 104 via a duplicate PCB trace 120c. The duplicate PCB trace 120c is identical in shape and electrical performance to PCB trace 110c.

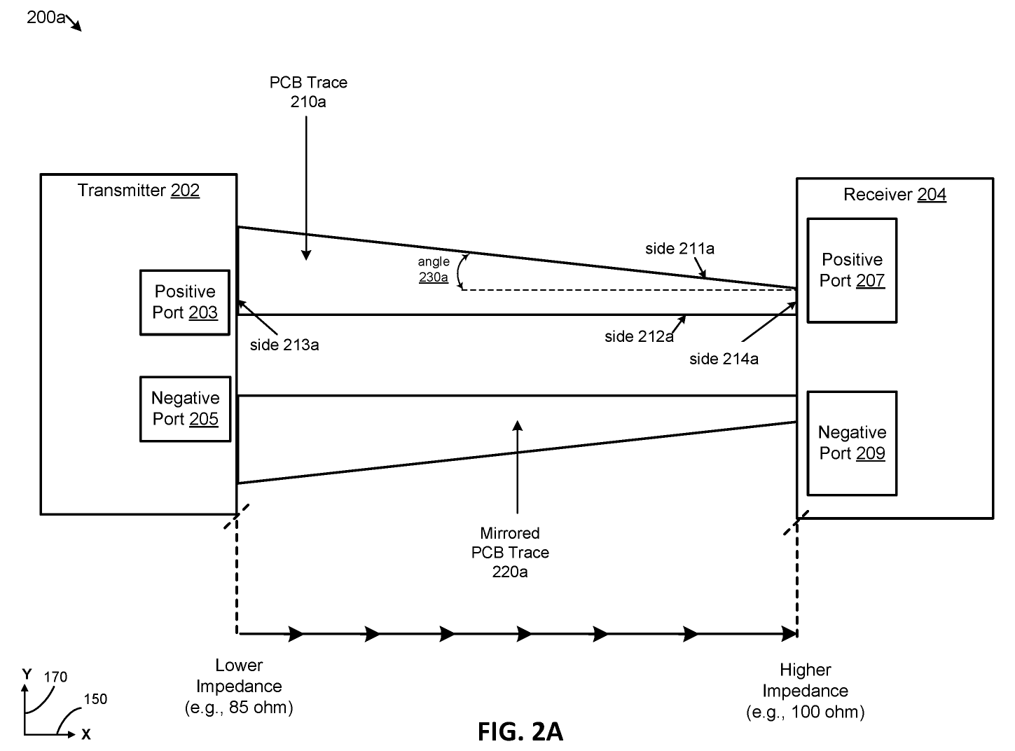

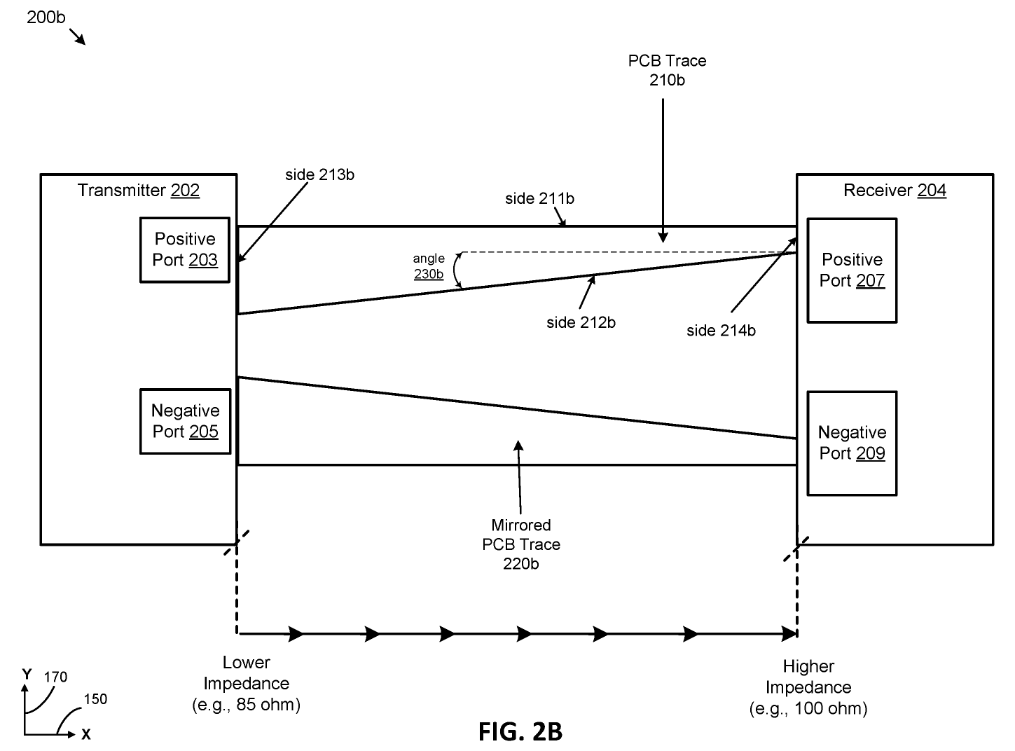

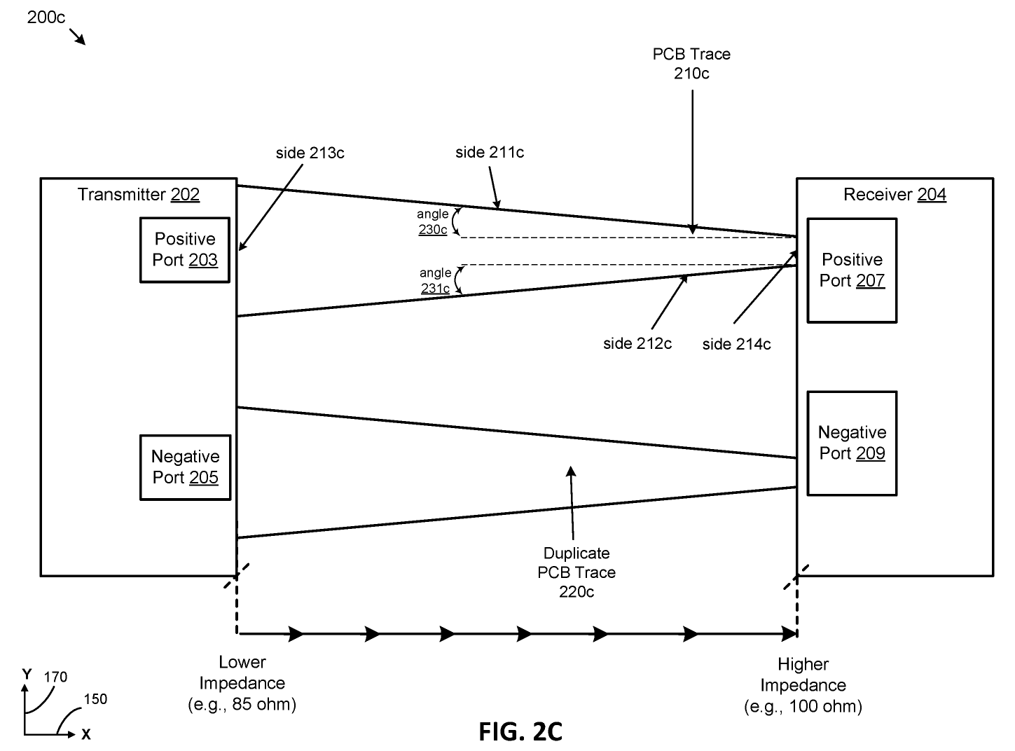

FIG. 2A illustrates an example high-speed electronic system including a low-impedance differential transmitter and a high-impedance differential receiver that communicate via an outer-edge-tapered PCB trace to resolve the impedance mismatch, in accordance with some embodiments. The high-speed electronic system 200a includes a transmitter 202, implemented as an IC device, and a receiver 204, which is also an IC device. The transmitter 202 includes a differential output interface consisting of a positive port 203 and a negative port 205. The receiver 204 includes a differential input interface consisting of a positive port 207 and a negative port 209. The differential output impedance of the transmitter 202 is lower than the differential input impedance of the receiver 204.

As shown in FIG. 2A, the differential output interface has an impedance of 85 ohms, while the differential input interface has an impedance of 100 ohms. However, other embodiments may exhibit different impedance mismatches. In such embodiments, each of the differential output interface and the differential input interface may have an impedance fixed at a value between 50 ohms and 100 ohms, provided that the output impedance remains lower than the input impedance.

The positive port 203 of the transmitter 202 is electrically coupled to the positive port 207 of the receiver 204 via a PCB trace 210a. The PCB trace 210a defines a closed geometric shape including four sides: side 211a having a first length, side 212a having a second length, side 213a having a third length, and side 214a having a fourth length.

Each of the four sides has a different length. For example, side 214a is shorter than side 213a, which is shorter than side 212a, which is shorter than the side 211a. Side 213a and side 214a extend vertically along the y-axis 170 and are parallel (or substantially parallel) to one another. Side 212a extends horizontally along the x-axis 150 between side 213a and side 214a. Side 211a also extends between side 213a and side 214a. The four sides complete the closed shape of the PCB trace 210a.

To mitigate the impedance mismatch resulting from the differential output interface of transmitter 202 having a lower impedance than the differential input interface of receiver 204, side 211a of PCB trace 210a is configured to be tapered. Specifically, side 211a slopes in the negative direction along the y-axis 170 as it extends from its connection with side 213a to its termination at side 214a. The angle 230a formed between side 211a and an imaginary horizontal line parallel to the x-axis 150 and originating at the positive port 207 may be equal to or fall within the range of approximately 0.01 degrees to 0.2 degrees, based on the absolute value.

The negative port 205 of the transmitter 202 is electrically coupled to the negative port 209 of the receiver 204 via a mirrored PCB trace 220a. The mirrored PCB trace 220a is identical in shape and electrical performance to PCB trace 210a, but is vertically flipped relative to PCB trace 210a.

FIG. 2B illustrates an example high-speed electronic system including a low-impedance differential transmitter and a high-impedance differential receiver that communicate via an inner-edge-tapered PCB trace to resolve the impedance mismatch, in accordance with some embodiments. The high-speed electronic system 200b includes the transmitter 202 and the receiver 204 in FIG. 2A, where the output interface of the transmitter 202 has a differential output impedance that is greater than the differential input impedance of the input interface of the receiver 204.

However, unlike the configuration in FIG. 2A, the output interface of the transmitter 202 is electrically coupled to the input interface of the receiver 204 via a PCB trace 210b. The PCB trace 210b defines a closed geometric shape including four sides: side 211b having a first length, side 212b having a second length, side 213b having a third length, and side 214b having a fourth length.

Each of the four sides has a different length. For example, side 214b is shorter than side 213b, which is shorter than side 211b, which is shorter than side 212b. Side 213b and side 214b extend vertically along the y-axis 170 and are parallel (or substantially parallel) to one another. Side 211b extends horizontally along the x-axis 150 between side 213b and side 214b. Side 212b also extends between side 213b and side 214b. The four sides complete the closed shape of the PCB trace 110b.

To mitigate the impedance mismatch resulting from the differential output interface of transmitter 202 having a lower impedance than the differential input interface of receiver 204, side 212b of PCB trace 210b is configured to be tapered. Specifically, side 212b slopes in the positive direction along the y-axis 170 as it extends from its connection with side 213b to its termination at side 214b. The angle 230b formed between side 212b and an imaginary horizontal line parallel to the x-axis 150 and originating at the positive port 207 may be equal to or fall within the range of approximately 0.01 degrees to 0.2 degrees, based on the absolute value.

The negative port 205 of the transmitter 202 is electrically coupled to the negative port 209 of the receiver 204 via a mirrored PCB trace 220b. The mirrored PCB trace 220b is identical in shape and electrical performance to PCB trace 210b, but is vertically flipped relative to PCB trace 210b.

FIG. 2C illustrates an example high-speed electronic system including a low-impedance differential transmitter and a high-impedance differential receiver that communicate via a dual-edge-tapered PCB trace to resolve the impedance mismatch, in accordance with some embodiments. The high-speed electronic system 200c includes the transmitter 202 and the receiver 204 in FIG. 2A, where the output interface of the transmitter 202 has a differential output impedance that is lower than the differential input impedance of the input interface of the receiver 104.

However, unlike the configuration in FIG. 2A, the output interface of the transmitter 202 is electrically coupled to the input interface of the receiver 204 via a PCB trace 210c. The PCB trace 210c defines a closed geometric shape including four sides: side 211c having a first length, side 212c having a second length, side 213c having a third length, and side 214c having a fourth length.

Two of the four sides have a different length, while the other two sides have the same length. For example, side 213c is longer than side 214c, while side 211c has the same length as side 212c. Side 213c and side 214c extend vertically along the y-axis 170 and are parallel (or substantially parallel) to one another. Side 211c and side 212c extend between side 213c and side 214c. All four sides complete the closed shape of the PCB trace 210c.

To mitigate the impedance mismatch resulting from the differential output interface of transmitter 202 having a lower impedance than the differential input interface of receiver 204, both side 211c and side 212c are configured to be tapered. Specifically, side 212c slopes in the positive direction along the y-axis 170 as it extends from its connection with side 213c to its termination at side 214c. Side 111c slopes in the negative direction along the y-axis 170 as it extends from its connection with side 213c to its termination at side 214c.

The angle 230c formed between side 211c and an imaginary horizontal line parallel to the x-axis 150 and originating at the positive port 207 may be equal to or fall within the range of approximately 0.01 degrees to 0.2 degrees, based on the absolute value. The angle 231c formed between side 212c and an imaginary horizontal line parallel to the x-axis 150 and originating at the positive port 207 may be equal to or fall within the range of approximately 0.01 degrees to 0.2 degrees, based on the absolute value.

The negative port 205 of the transmitter 202 is electrically coupled to the negative port 209 of the receiver 204 via a duplicate PCB trace 220c. The duplicate PCB trace 220c is identical in shape and electrical performance to PCB trace 210c.

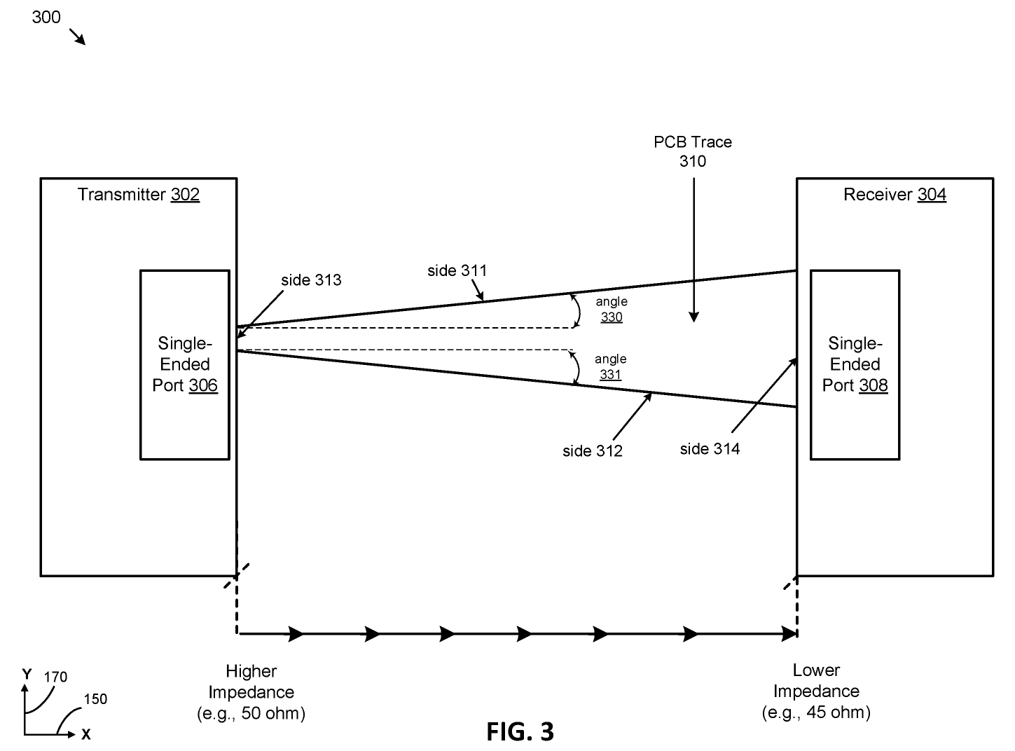

FIG. 3 illustrates an example high-speed electronic system including a high-impedance single-ended transmitter and a low-impedance single-ended receiver that communicate via a dual-edge-tapered PCB trace to resolve the impedance mismatch, in accordance with some embodiments. The high-speed electronic system 300 includes a transmitter 302, implemented as an IC device, and a receiver 304, which is also an IC device. The transmitter 302 includes a single-ended port 306 and the receiver 304 includes a single-ended port 308. The single-ended output impedance of the transmitter 202 is higher than the single-ended input impedance of the receiver 204.

As shown in FIG. 3, the single-ended port 306 has an impedance of 50 ohms, while the single-ended port 306 has an impedance of 45 ohms. However, other embodiments may exhibit different impedance mismatches. In such embodiments, each of the single-ended input and output ports may have an impedance fixed at a value between 40 ohms and 60 ohms, provided that the output impedance remains higher than the input impedance.

The single-ended port 306 of the transmitter 202 is electrically coupled to the single-ended port 308 of the receiver 204 via a PCB trace 310. The PCB trace 310 defines a closed geometric shape including four sides: side 311 having a first length, side 312 having a second length, side 313 having a third length, and side 314 having a fourth length.

Two of the four sides have a different length, while the other two sides have the same length. For example, side 313 is longer than side 314, while side 311 has the same length as side 312. Side 313 and side 314 extend vertically along the y-axis 170 and are parallel (or substantially parallel) to one another. Side 311 and side 312 extend between side 313 and side 314. All four sides complete the closed shape of the PCB trace 310.

To mitigate the impedance mismatch resulting from the single-ended port 306 of transmitter 202 having a higher impedance than the single-ended port 308 of receiver 304, both side 311 and side 312 are configured to be tapered. Specifically, side 312 slopes in the negative direction along the y-axis 170 as it extends from its connection with side 313 to its termination at side 314. Side 311 slopes in the positive direction along the y-axis 170 as it extends from its connection with side 313 to its termination at side 314.

The angle 330 formed between side 311 and an imaginary horizontal line parallel to the x-axis 150 and originating at the single-ended port 306 may be equal to or fall within the range of approximately 0.01 degrees to 0.2 degrees, based on the absolute value. The angle 331 formed between side 312 and an imaginary horizontal line parallel to the x-axis 150 and originating at the single-ended port 308 may be equal to or fall within the range of approximately 0.01 degrees to 0.2 degrees, based on the absolute value.

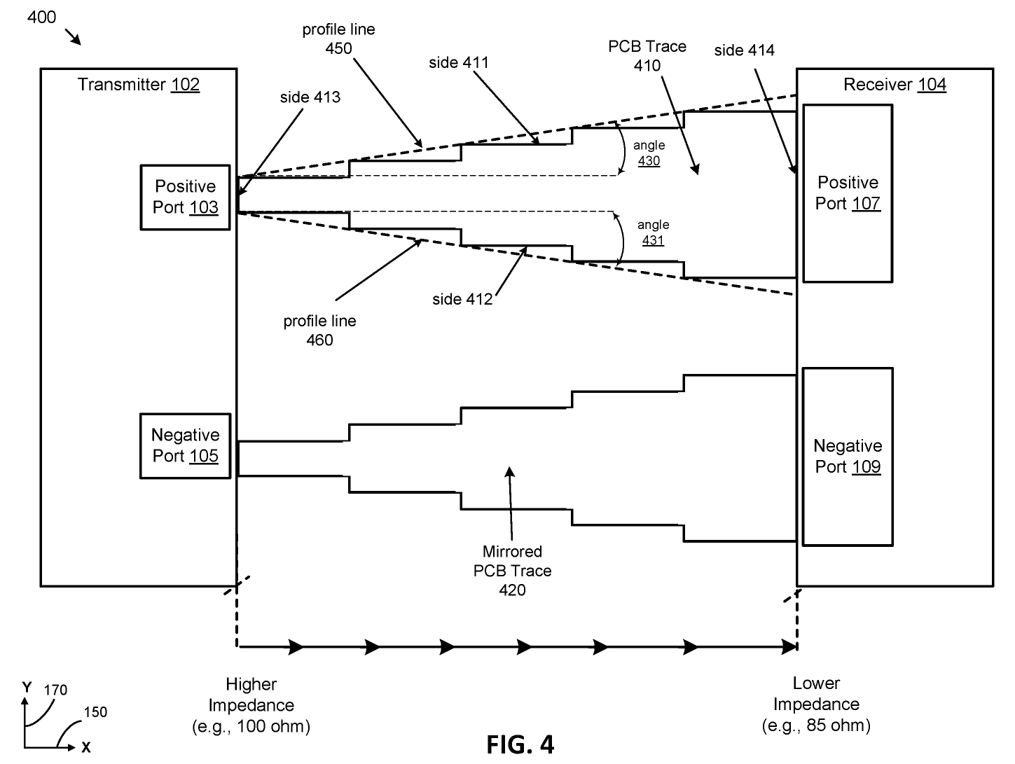

FIG. 4 illustrates an example high-speed electronic system including a high-impedance differential transmitter and a low-impedance differential receiver that communicate via a piece-wise tapered PCB trace to resolve the impedance mismatch, in accordance with some embodiments. The high-speed electronic system 400 includes the transmitter 102 and receiver 104, each from FIG. 1A.

The positive port 103 of transmitter 102 is electrically coupled to the positive port 107 of the receiver 104 via a PCB trace 410. The PCB trace 410 defines a closed geometric shape including four sides: side 411 having a first length, side 412 having a second length, side 413 having a third length, and side 414 having a fourth length.

Two of the four sides have a different length, while the other two sides have the same length. For example, side 413 is shorter than side 414, while side 411 has the same length as side 412. Side 413 and side 414 extend vertically along the y-axis 170 and are parallel (or substantially parallel) to one another. Side 411 and side 412 extend between side 413 and side 414. All four sides complete the closed shape of the PCB trace 410.

To mitigate the impedance mismatch resulting from the positive port 103 of transmitter 102 having a higher impedance than the positive port 107 of receiver 104, both side 411 and side 412 are configured to be tapered in a non-linear fashion, such as a piecewise taper. For example, as shown in FIG. 4, PCB trace 410 exhibits piecewise tapering, where side 411 includes stepped segments that incrementally rise at various intervals along its length, and side 412 includes stepped segments that incrementally fall at various intervals along its length. In other embodiments, PCB trace 410 may be implemented using alternative forms of non-linear tapering, such as polynomial tapering, exponential tapering, or Klopfenstein tapering.

Additionally, an imaginary outer profile line 450 adjacent to side 411 exhibits a positive slope due to the cumulative rise of the stepped segments. The angle 430 formed between profile line 450 and an imaginary horizontal line parallel to the x-axis 150 and originating at the positive port 103 may be equal to or fall within the range of approximately 0.01 degrees to 0.2 degrees, based on the absolute value.

An imaginary outer profile line 460 adjacent to side 412 exhibits a negative slope due to the cumulative fall of the stepped segments. The angle 431 formed between profile line 460 and an imaginary horizontal line parallel to the x-axis 150 and originating at the negative port 105 may be equal to or fall within the range of approximately 0.01 degrees to 0.2 degrees, based on the absolute value.

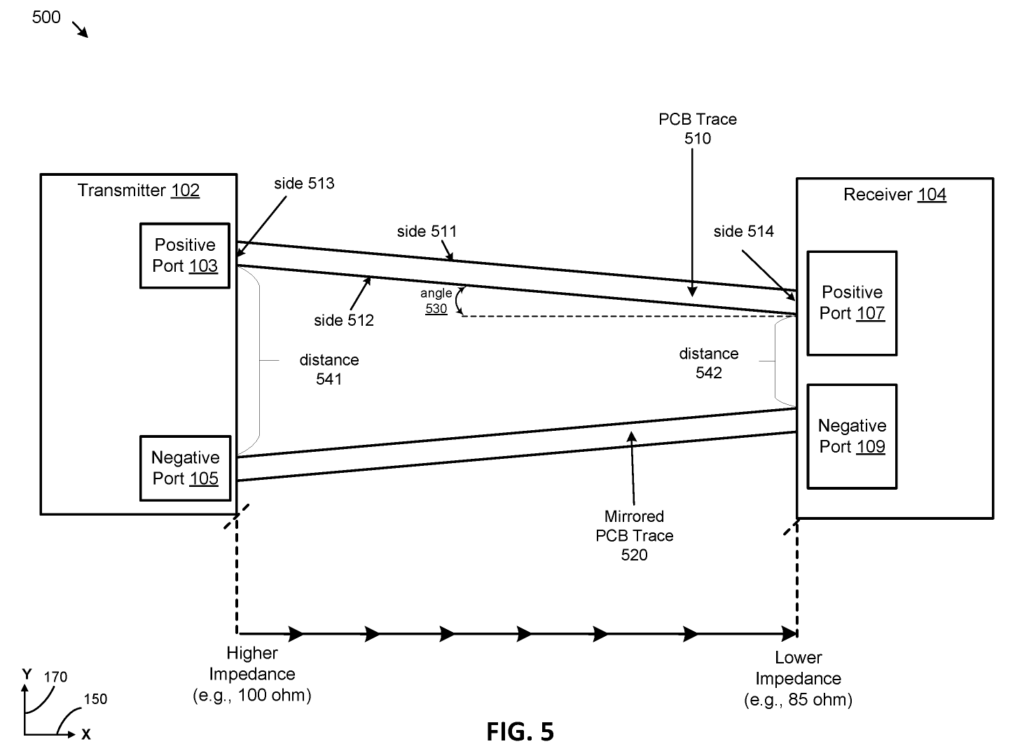

FIG. 5 illustrates an example high-speed electronic system including a high-impedance differential transmitter and a low-impedance differential receiver that communicate via a tapered PCB trace with decreasing trace spacing to resolve the impedance mismatch, in accordance with some embodiments. The high-speed electronic system 500 includes the transmitter 102 and receiver 104, each from FIG. 1A.

The positive port 103 of transmitter 102 is electrically coupled to the positive port 107 of the receiver 104 via a PCB trace 510. The PCB trace 510 defines a closed geometric shape including four sides: side 511 having a first length, side 512 having a second length, side 513 having a third length, and side 514 having a fourth length.

Side 513 and side 514 extend vertically along the y-axis 170 and are parallel (or substantially parallel) to one another. Side 511 and side 512 extend between side 511 and side 512 and are parallel (or substantially parallel) to one another. All four sides complete the closed shape of the PCB trace 510.

To mitigate the impedance mismatch resulting from the positive port 103 of transmitter 102 having a higher impedance than the positive port 107 of receiver 104, both side 511 and side 512 are configured to be tapered. Specifically, both side 511 and side 512 slope in the negative direction along the y-axis 170 as it extends from its connection with side 513 to its termination at side 514. The angle 530 formed between side 512 and an imaginary horizontal line parallel to the x-axis 150 and originating at the positive port 103 may be equal to or fall within the range of approximately 0.01 degrees to 0.2 degrees, based on the absolute value.

The negative port 105 of the transmitter 102 is electrically coupled to the negative port 109 of the receiver 104 via a mirrored PCB trace 520. The mirrored PCB trace 520 is identical in shape and electrical performance to PCB trace 510, but is vertically flipped relative to PCB trace 510.

Accordingly, distance 541 is larger than distance 542. This spacing between side 512 of PCB trace 510 and the corresponding side of mirrored PCB trace 520 decreases progressively along the signal path from transmitter 102 to receiver 104, which helps to mitigate the impedance mismatch between the transmitter 102 and receiver 104.

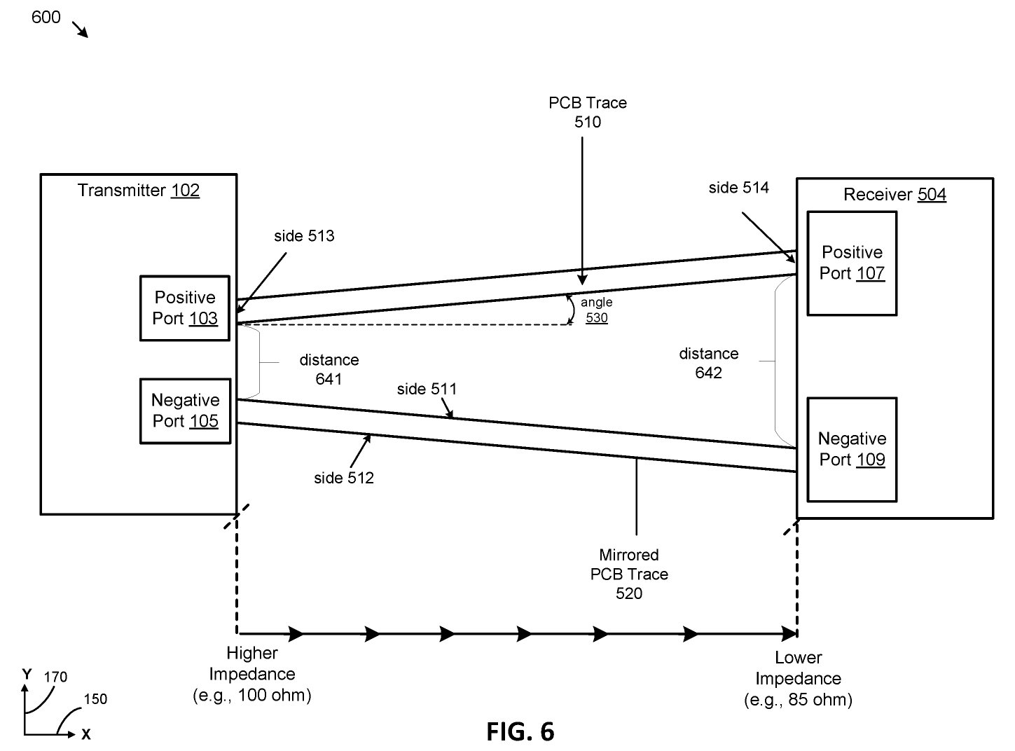

FIG. 6 illustrates an example high-speed electronic system including a high-impedance differential transmitter and a low-impedance differential receiver that communicate via a tapered PCB trace with increasing trace spacing to resolve the impedance mismatch, in accordance with some embodiments. The high-speed electronic system 600 includes all the same components as high-speed electronic system 500 in FIG. 5.

However, unlike FIG. 5, PCB trace 510 high-speed electronic system 600 slopes in the positive direction along the y-axis 170 as it extends from its connection with transmitter 102 to its termination at receiver 604.

Accordingly, distance 641 is shorter than distance 542. This spacing between side 512 of PCB trace 510 and the corresponding side of mirrored PCB trace 520 decreases progressively along the signal path from transmitter 102 to receiver 104, which helps to mitigate the impedance mismatch between the transmitter 102 and receiver 104.

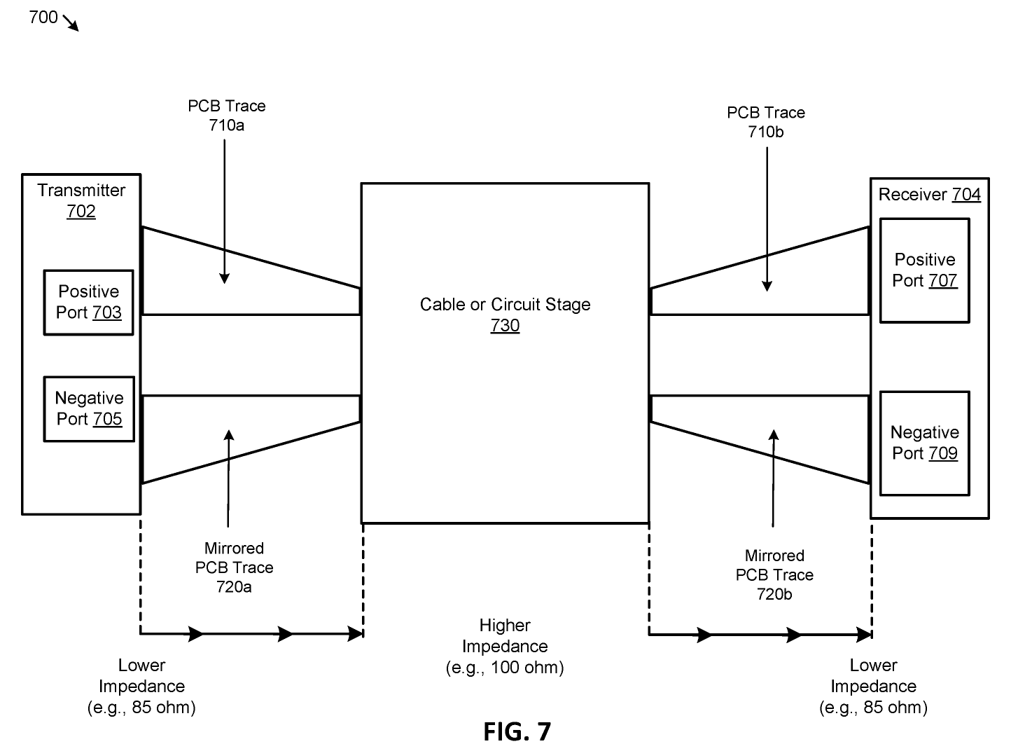

FIG. 7 illustrates an example high-speed electronic system including a low-impedance differential transmitter and a high-impedance differential receiver that communicate across a cable or discrete device using multiple tapered PCB traces to resolve multiple impedance mismatches, in accordance with some embodiments. The high-speed electronic system 700 includes a transmitter 702 consisting of a positive port 703 and a negative port 705, a cable or circuit stage 730, and a receiver 704 consisting of a positive port 707 and a negative port 709.

The cable may be 100BASE-T1 unshielded twisted pair (UTP). A circuit stage may be one or more capacitors, inductors, transistors, resistors, or the like.

The transmitter 702 has an output impedance that is lower than an input of the cable or circuit stage 730. The receiver 704 has an input impedance that is lower than the output impedance of an output of the cable or circuit stage 730.

As shown in FIG. 7, PCB trace 710a and mirrored PCB trace 720a are configured to mitigate the impedance mismatch between the transmitter 702 and the cable or circuit stage 730, and PCB trace 710b and mirrored PCB trace 720b are configured to mitigate the impedance mismatch the cable or circuit stage 730 and the receiver 704. In some embodiments, PCB trace 710a (and its corresponding mirrored PCB trace 720a) and PCB trace 710b (and its corresponding mirrored PCB trace 720b) may be implemented using any of the various PCB trace configurations disclosed in FIGS. 1A-6.

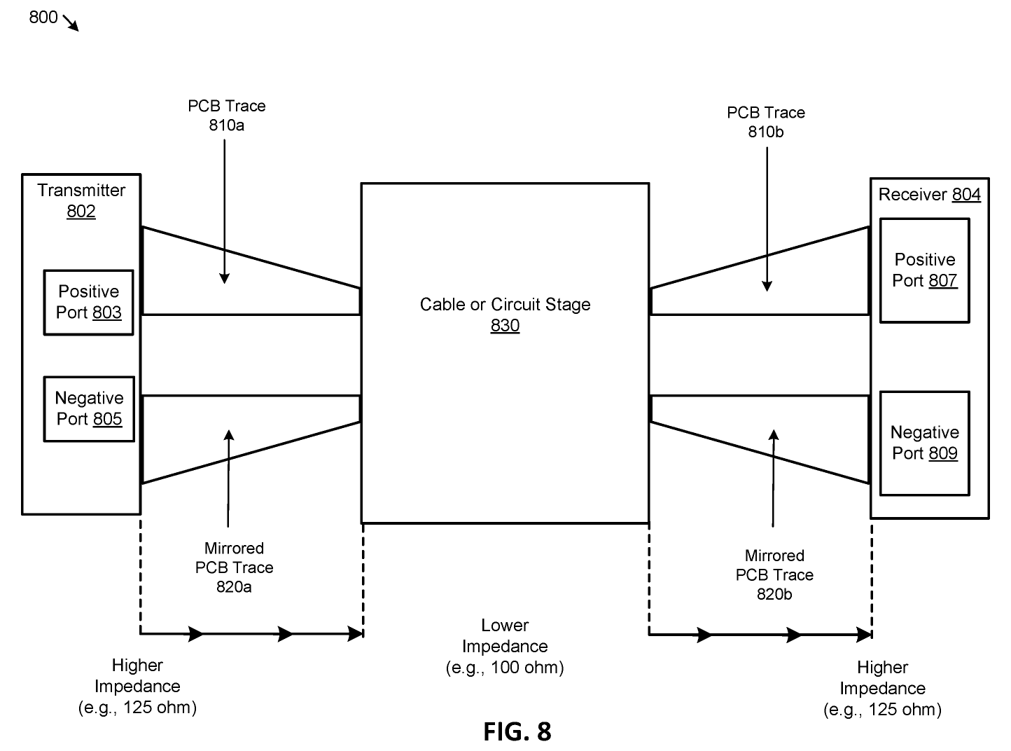

FIG. 8 illustrates an example high-speed electronic system including a high-impedance differential transmitter and a low-impedance differential receiver that communicate across a cable or discrete device using multiple tapered PCB traces to resolve multiple impedance mismatches, in accordance with some embodiments. The high-speed electronic system 800 includes a transmitter 802 consisting of a positive port 803 and a negative port 805, a cable or circuit stage 830, and a receiver 804 consisting of a positive port 807 and a negative port 809.

The transmitter 802 has an output impedance that is higher than an input of the cable or circuit stage 830. The receiver 804 has an input impedance that is higher than the output impedance of an output of the cable or circuit stage 830.

As shown in FIG. 8, PCB trace 810a and mirrored PCB trace 820a are configured to mitigate the impedance mismatch between the transmitter 802 and the cable or circuit stage 830, and PCB trace 810b and mirrored PCB trace 820b are configured to mitigate the impedance mismatch the cable or circuit stage 830 and the receiver 804. In some embodiments, PCB trace 810a (and its corresponding mirrored PCB trace 820a) and PCB trace 810b (and its corresponding mirrored PCB trace 820b) may be implemented using any of the various PCB trace configurations disclosed in FIGS. 1A-6.

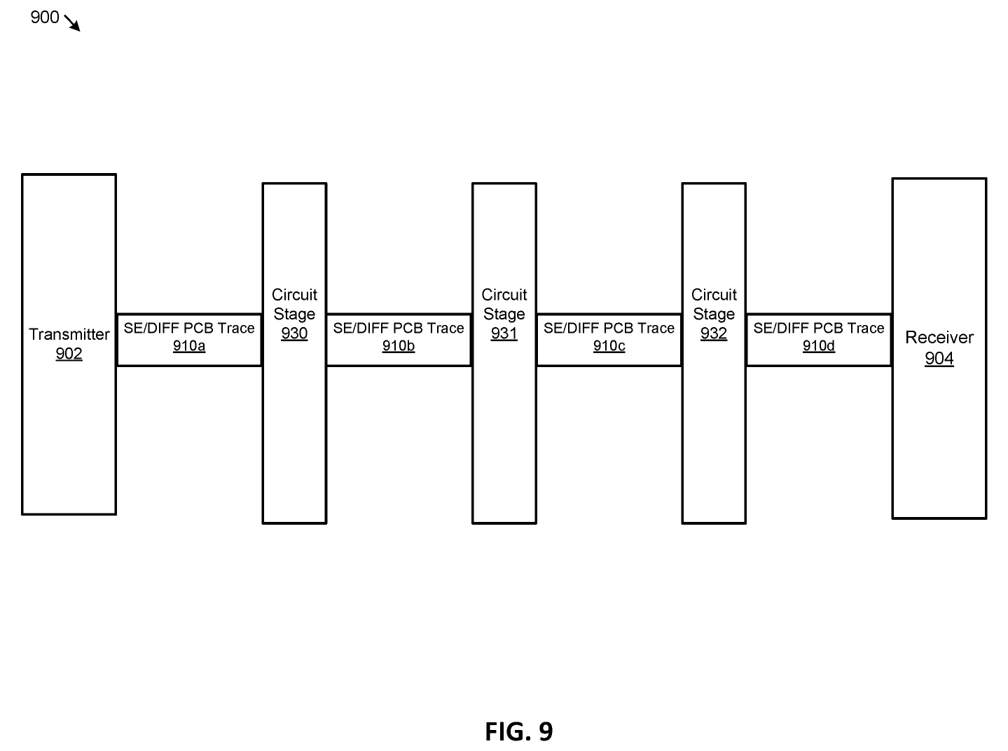

FIG. 9 illustrates an example high-speed electronic system including a single-ended or differential transmitter and a single-ended or differential receiver that communicate across multiple circuit stages using multiple single-ended or differential PCB traces, in accordance with some embodiments. Specifically, the high-speed electronic system 900 includes a single-ended or differential transmitter 902, a single-ended or differential receiver 904, and multiple circuit stages (e.g., circuit stages 930-932) that may be associated with different input and output impedance values. The multiple single-ended or differential PCB traces (e.g., SE/DIFF PCB traces 910a-910d) between these components are configured to mitigate the impedance mismatches between components. In some embodiments, the differential PCB traces depicted in FIG. 9 may be implemented using any of the various PCB trace configurations disclosed in FIGS. 1A-6.

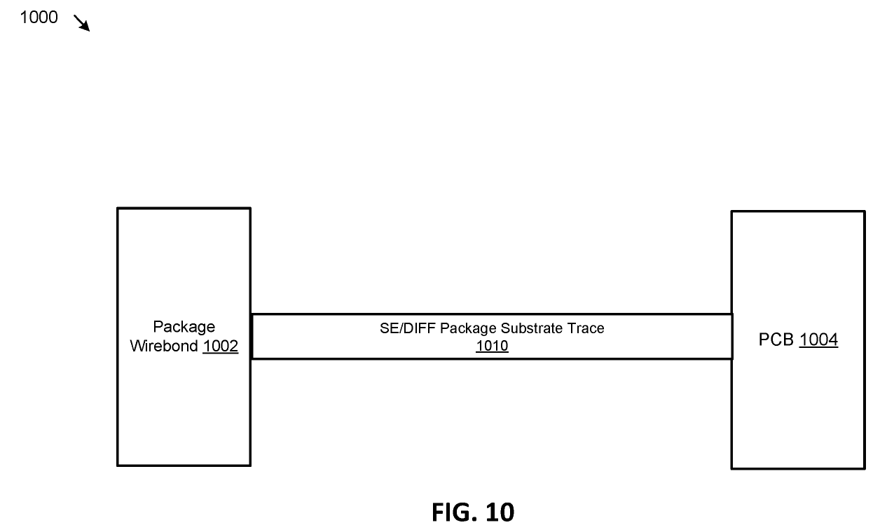

FIG. 10 illustrates an example semiconductor package configured to resolve impedance matching between wirebonds and PCB, in accordance with some embodiments. As shown in FIG. 10, a package wirebond 1002 of the semiconductor package 1000 may be electrically coupled to PCB 1004 via single-ended or differential (SE/DIFF) package substrate trace 1010, which is configured to mitigate impedance mismatches between the package wirebond 1002 and the PCB 1004. The semiconductor package 1000 includes multiple package wirebonds 1002 that are connected to various locations on the PCB 1004.

In some embodiments, the SE/DIFF package substrate trace 1010 may be implemented using any of the various PCB trace configurations disclosed in FIGS. 1A-6.

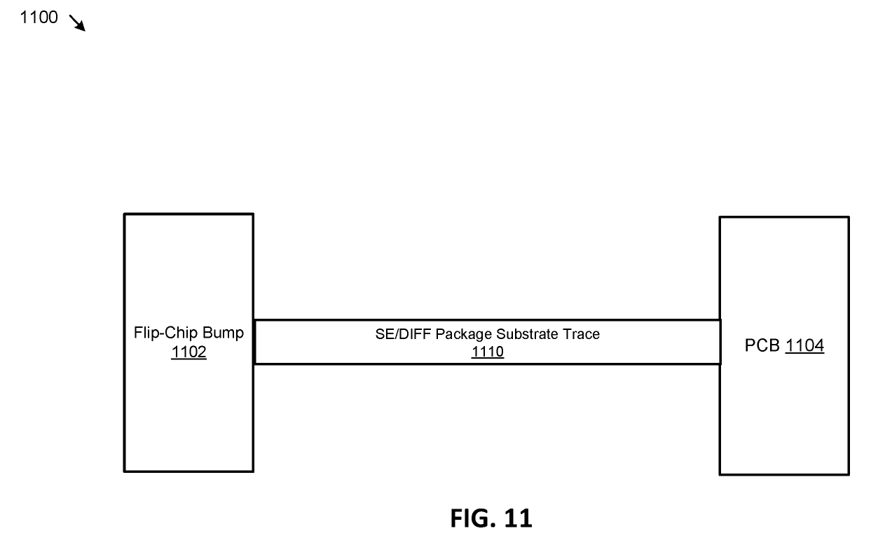

FIG. 11 illustrates an example semiconductor package configured to resolve impedance matching between wirebonds and PCB, in accordance with some embodiments. As shown in FIG. 11, a flip-chip bump 1102 of the semiconductor package 1100 may be electrically coupled to PCB 1104 via single-ended or differential (SE/DIFF) package substrate trace 1110, which is configured to mitigate impedance mismatches between the flip-chip bump 1102 and the PCB 1104. The semiconductor package 1100 includes multiple package substrate trace 1110 that are connected to various locations on the PCB 1104, such as via a ball gate array (BGA).

In some embodiments, the SE/DIFF package substrate trace 1110 may be implemented using any of the various PCB trace configurations disclosed in FIGS. 1A-6.

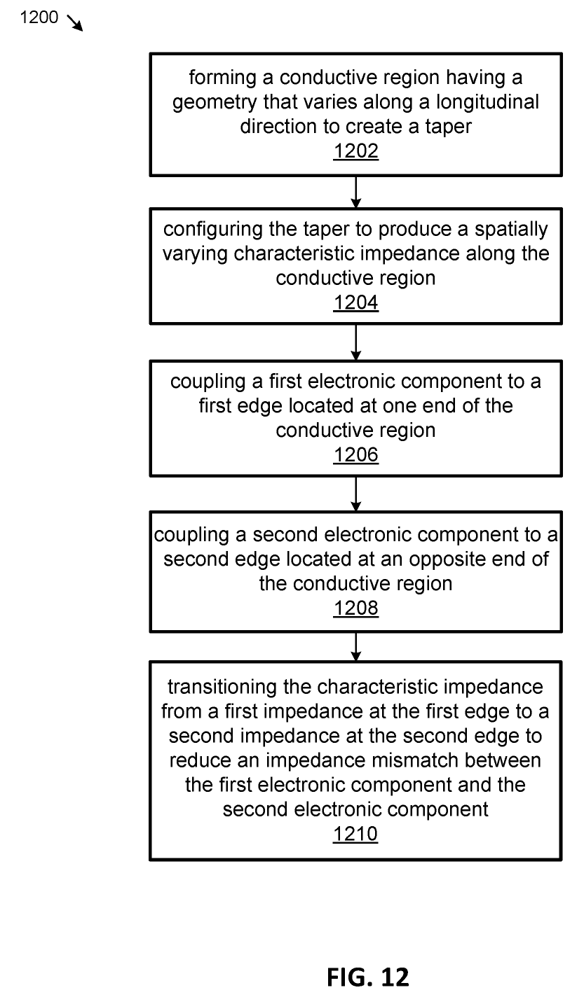

FIG. 12 is a flow diagram of a method of mitigating impedance mismatches in high-speed electronic systems using taper routing techniques implemented within PCBs and semiconductor packages. Although the operations are depicted in FIG. 12 as integral operations in a particular order for purposes of illustration, in other implementations, one or more operations, or portions thereof, are performed in a different order, or overlapping in time, in series or parallel, or are omitted, or one or more additional operations are added, or the method is changed in some combination of ways. In some embodiments, the method 1200 may be performed by processing logic that includes hardware (e.g., circuitry, dedicated logic, programmable logic, microcode, etc.), firmware, or a combination thereof. In some embodiments, some or all operations of method 1200 may be performed using semiconductor manufacturing equipment.

As shown in FIG. 12, the method 1200 includes the operation 1202 of forming a conductive region having a geometry that varies along a longitudinal direction to create a taper. The method 1200 includes the operation 1204 of configuring the taper to produce a spatially varying characteristic impedance along the conductive region. The method 1200 includes the operation 1206 of coupling a first electronic component to a first edge located at one end of the conductive region. The method 1200 includes the operation 1208 of coupling a second electronic component to a second edge located at an opposite end of the conductive region. The method 1200 includes the operation 1210 of transitioning the characteristic impedance from a first impedance at the first edge to a second impedance at the second edge to reduce an impedance mismatch between the first electronic component and the second electronic component.

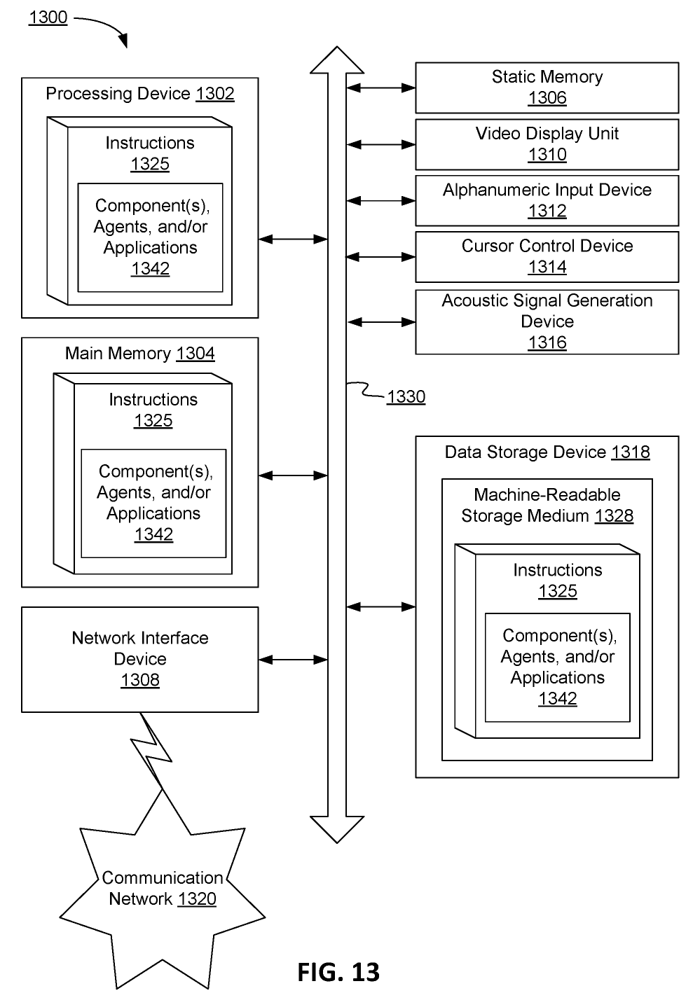

FIG. 13 is a block diagram of an example computing device that may perform one or more of the operations described herein, in accordance with some embodiments. Computing device 1300 may be connected to other computing devices in a LAN, an intranet, an extranet, and/or the Internet. The computing device may operate in the capacity of a server machine in client-server network environment or in the capacity of a client in a peer-to-peer network environment. The computing device may be provided by a personal computer (PC), a set-top box (STB), a server, a network router, switch or bridge, or any machine capable of executing a set of instructions (sequential or otherwise) that specify actions to be taken by that machine. Further, while only a single computing device is illustrated, the term “computing device” shall also be taken to include any collection of computing devices that individually or jointly execute a set (or multiple sets) of instructions to perform the methods discussed herein.

The example computing device 1300 may include a processing device (e.g., a general-purpose processor, a PLD, etc.) 1302, a main memory 1304 (e.g., synchronous dynamic random-access memory (DRAM), read-only memory (ROM)), a static memory 1306 (e.g., flash memory and a data storage device 1318), which may communicate with each other via a bus 1330.

Processing device 1302 may be provided by one or more general-purpose processing devices such as a microprocessor, central processing unit, or the like. In an illustrative example, processing device 1302 may include a complex instruction set computing (CISC) microprocessor, reduced instruction set computing (RISC) microprocessor, very long instruction word (VLIW) microprocessor, or a processor implementing other instruction sets or processors implementing a combination of instruction sets. Processing device 1302 may also include one or more special-purpose processing devices such as an application specific integrated circuit (ASIC), a field programmable gate array (FPGA), a digital signal processor (DSP), network processor, or the like. The processing device 1302 may be configured to execute the operations described herein, in accordance with one or more aspects of the present disclosure, for performing the operations and steps discussed herein.

Computing device 1300 may further include a network interface device 1308 which may communicate with a communication network 1320. The computing device 1300 also may include a video display unit 1310 (e.g., a liquid crystal display (LCD) or a cathode ray tube (CRT)), an alphanumeric input device 1312 (e.g., a keyboard), a cursor control device 1314 (e.g., a mouse) and an acoustic signal generation device 1316 (e.g., a speaker). In one embodiment, video display unit 1310, alphanumeric input device 1312, and cursor control device 1314 may be combined into a single component or device (e.g., an LCD touch screen).

Data storage device 1318 may include a computer-readable storage medium 1328 on which may be stored one or more sets of instructions 1325 that may include instructions for one or more components/programs/applications 1342 for carrying out the operations (e.g., operations of method 900 in FIG. 9) described herein, in accordance with one or more aspects of the present disclosure. Instructions 1325 may also reside, completely or at least partially, within main memory 1304 and/or within processing device 1302 during execution thereof by computing device 1300, main memory 1304 and processing device 1302 also constituting computer-readable media. The instructions 1325 may further be transmitted or received over a communication network 1320 via network interface device 1308.

While computer-readable storage medium 1328 is shown in an illustrative example to be a single medium, the term “computer-readable storage medium” should be taken to include a single medium or multiple media (e.g., a centralized or distributed database and/or associated caches and servers) that store the one or more sets of instructions. The term “computer-readable storage medium” shall also be taken to include any medium that is capable of storing, encoding or carrying a set of instructions for execution by the machine and that cause the machine to perform the methods described herein. The term “computer-readable storage medium” shall accordingly be taken to include, but not be limited to, solid-state memories, optical media and magnetic media.

In the above description, some portions of the detailed description are presented in terms of algorithms and symbolic representations of operations on analog signals and/or digital signals or data bits within a non-transitory storage medium. These algorithmic descriptions and representations are the means used by those skilled in the data processing arts to most effectively convey the substance of their work to others skilled in the art. An algorithm is here and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared and otherwise manipulated. It has proven convenient at times, principally for reasons of common usage, to refer to these signals as bits, values, elements, symbols, characters, terms, numbers, or the like.

Reference in the description to “an embodiment,” “one embodiment,” “an example embodiment,” “some embodiments,” and “various embodiments” means that a particular feature, structure, step, operation, or characteristic described in connection with the embodiment(s) is included in at least one embodiment of the disclosure. Further, the appearances of the phrases “an embodiment,” “one embodiment,” “an example embodiment,” “some embodiments,” and “various embodiments” in various places in the description do not necessarily all refer to the same embodiment(s).

The description includes references to the accompanying drawings, which form a part of the detailed description. The drawings show illustrations in accordance with exemplary embodiments. These embodiments, which may also be referred to herein as “examples,” are described in enough detail to enable those skilled in the art to practice the embodiments of the claimed subject matter described herein. The embodiments may be combined, other embodiments may be utilized, or structural, logical, and electrical changes may be made without departing from the scope and spirit of the claimed subject matter. The embodiments described herein are not intended to limit the scope of the subject matter but rather to enable one skilled in the art to practice, make, and/or use the subject matter.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “forming,” “configuring,” “coupling,” “providing,” “transitioning,” or the like, refer to the actions and processes of an integrated circuit (IC) controller , or similar electronic device, that manipulates and transforms data represented as physical (e.g., electronic) quantities within the controller's registers and memories into other data similarly represented as physical quantities within the controller memories or registers or other such information non-transitory storage medium.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such.

Embodiments described herein may also relate to an apparatus (e.g., such as an AC-DC converter, and/or an ESD protection system/circuit) for performing the operations herein. This apparatus may be specially constructed for the required purposes, or it may include firmware or hardware logic selectively activated or reconfigured by the apparatus. Such firmware may be stored in a non-transitory computer-readable storage medium, such as, but not limited to, read-only memories (ROMs), random access memories (RAMs), EPROMs, EEPROMs, flash memory, or any type of media suitable for storing electronic instructions. The term “computer-readable storage medium” should be taken to include a single medium or multiple media that store one or more sets of instructions. The term “computer-readable medium” shall also be taken to include any medium that is capable of storing, encoding, or carrying a set of instructions for execution by the machine and that causes the machine to perform any one or more of the methodologies of the present embodiments. The term “computer-readable storage medium” shall accordingly be taken to include, but not be limited to, solid-state memories, optical media, magnetic media, any medium that is capable of storing a set of instructions for execution by the machine and that causes the machine to perform any one or more of the methodologies of the present embodiments.

The above description sets forth numerous specific details such as examples of specific systems, components, methods, and so forth, to provide a good understanding of several embodiments of the present disclosure. It is to be understood that the above description is intended to be illustrative and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A signal routing system comprising:
a conductive region having a geometry that varies along a longitudinal direction to form a taper, the taper being configured to produce a spatially varying characteristic impedance along the conductive region;
wherein the characteristic impedance transitions from a first impedance at a first edge located at one end of the conductive region to a second impedance at a second edge located at an opposite end of the conductive region; and
wherein the spatially varying characteristic impedance is configured to reduce an impedance mismatch between a first electronic component coupled to the first edge and a second electronic component coupled to the second edge.

2. The signal routing system of claim 1, wherein
a third edge of the conductive region connects a first location of the first edge to a first location of the second edge; and
a fourth edge of the conductive region connects a second location of the first edge to a second location of the second edge.

3. The signal routing system of claim 2, wherein the first impedance at the first edge is higher than the second impedance at the second edge, the first edge is shorter than the second edge; and at least one of:
the third edge tapers along the longitudinal direction from the first edge to the second edge, such that the third edge extends from the first location of the first edge to the first location of the second edge at a positive taper angle relative to the longitudinal direction; or
the fourth edge tapers along the longitudinal direction from the first edge to the second edge, such that the fourth edge extends from the second location of the first edge to the second location of the second edge at a negative taper angle relative to the longitudinal direction.

4. The signal routing system of claim 3, wherein an absolute value of the positive taper angle or the negative taper angle is within a range of 0.01 degrees to 0.2 degrees.

5. The signal routing system of claim 2, wherein the first impedance at the first edge is lower than the second impedance at the second edge, the first edge is longer than the second edge, and at least one of:
the third edge tapers along the longitudinal direction from the first edge to the second edge, such that the third edge extends from the first location of the first edge to the first location of the second edge at a negative taper angle relative to the longitudinal direction; or
the fourth edge tapers along the longitudinal direction from the first edge to the second edge, such that the fourth edge extends from the second location of the first edge to the second location of the second edge at a positive taper angle relative to the longitudinal direction.

6. The signal routing system of claim 5, wherein an absolute value of the positive taper angle or the negative taper angle is within a range of 0.01 degrees to 0.2 degrees.

7. The signal routing system of claim 2, wherein
the taper is implemented as a piecewise taper comprising two or more segments having different taper angles; and
the taper is formed by a variation in geometry along at least one of the third edge or the fourth edge.

8. The signal routing system of claim 1, wherein the first electronic component is a transmitter and the second electronic component is a receiver, and further comprising:
a second conductive region that is substantially identical in shape and electrical performance to the conductive region,
wherein the second conductive region is disposed in a vertically flipped orientation relative to the conductive region;
wherein the conductive region is coupled to a positive port of the transmitter and a positive port of the receiver, and the second conductive region is coupled to a negative port of the transmitter and a negative port of the receiver.

9. The signal routing system of claim 1, further comprising:
a second conductive region coupled to the first electronic component and the second electronic component,
wherein the conductive region and the second conductive region each have a substantially identical width; and
wherein a spacing between the conductive region and the second conductive region varies along the longitudinal direction, such that the spacing either increases or decreases as the conductive region and the second conductive region approach the second electronic component.

10. The signal routing system of claim 1, further comprising:
a second conductive region coupled between the second electronic component and a third electronic component,
wherein the second conductive region has a geometry that varies along a second longitudinal direction to form a second taper, the second taper being configured to produce a second spatially varying characteristic impedance along the second conductive region; and
wherein the second spatially varying characteristic impedance is configured to reduce a second impedance mismatch between the second electronic component and the third electronic component.

11. The signal routing system of claim 1, wherein the conductive region is implemented in a semiconductor package substrate and is configured to compensate for the impedance mismatch associated with at least one of a wirebond, a flip-chip bump, or a ball grid array (BGA).

12. A method comprising:
forming a conductive region having a geometry that varies along a longitudinal direction to create a taper;
configuring the taper to produce a spatially varying characteristic impedance along the conductive region;
coupling a first electronic component to a first edge located at one end of the conductive region;
coupling a second electronic component to a second edge located at an opposite end of the conductive region; and
transitioning the characteristic impedance from a first impedance at the first edge to a second impedance at the second edge to reduce an impedance mismatch between the first electronic component and the second electronic component.

13. The method of claim 12, further comprising:
forming a third edge of the conductive region to connect a first location of the first edge to a first location of the second edge; and
forming a fourth edge of the conductive region to connect a second location of the first edge to a second location of the second edge.

14. The method of claim 13, wherein the first impedance at the first edge is higher than the second impedance at the second edge, the first edge is shorter than the second edge; and at least one of:
tapering the third edge along the longitudinal direction from the first edge to the second edge at a positive taper angle; or
tapering the fourth edge along the longitudinal direction from the first edge to the second edge at a negative taper angle.

15. The method of claim 13, wherein the first impedance at the first edge is lower than the second impedance at the second edge, the first edge is longer than the second edge; and at least one of:
tapering the third edge along the longitudinal direction from the first edge to the second edge at a negative taper angle; or
tapering the fourth edge along the longitudinal direction from the first edge to the second edge at a positive taper angle.

16. The method of claim 13, further comprising:
implementing the taper as a piecewise taper comprising two or more segments having different taper angles; and
forming the taper by varying the geometry along at least one of the third edge or the fourth edge.

17. The method of claim 12, wherein the first electronic component is a transmitter and the second electronic component is a receiver, and further comprising:
forming a second conductive region substantially identical in shape and electrical performance to the conductive region;
disposing the second conductive region in a vertically flipped orientation relative to the conductive region;
coupling the conductive region to a positive port of the transmitter and a positive port of the receiver; and
coupling the second conductive region to a negative port of the transmitter and a negative port of the receiver.

18. The method of claim 12, further comprising:
forming a second conductive region coupled to the first electronic component and the second electronic component;
ensuring the conductive region and the second conductive region each have a substantially identical width; and
varying a spacing between the conductive region and the second conductive region along the longitudinal direction, such that the spacing either increases or decreases as the conductive region and the second conductive region approach the second electronic component.

19. The method of claim 12, further comprising:
forming a second conductive region coupled between the second electronic component and a third electronic component;
varying the geometry of the second conductive region along a second longitudinal direction to form a second taper;
configuring the second taper to produce a second spatially varying characteristic impedance along the second conductive region; and
reducing a second impedance mismatch between the second electronic component and the third electronic component using the second spatially varying characteristic impedance.

20. A high-speed electronic system comprising:
a transmitter;
a receiver; and
a conductive region coupled between the transmitter and the receiver;
wherein the conductive region has a geometry that varies along a longitudinal direction to form a taper, the taper being configured to produce a spatially varying characteristic impedance along the conductive region;
wherein the characteristic impedance transitions from a first impedance at a first edge located at one end of the conductive region to a second impedance at a second edge located at an opposite end of the conductive region; and
wherein the spatially varying characteristic impedance is configured to reduce an impedance mismatch between the transmitter coupled to the first edge and the receiver coupled to the second edge.
